(19) United States
(12) Patent Application Publication
(10) Pub. No.: US 2025/0391772 A1
(43) Pub. Date: Dec. 25, 2025

(54) INTEGRATED CIRCUIT RESISTIVE STRUCTURE VALIDATION FOR AUTHENTICATION

(71) Applicant: International Business Machines Corporation, Armonk, NY (US)

(72) Inventors: Nicholas LATHAM, Albany, NY (US); Junwon HAN, Loudonville, NY (US); Viswas PUROHIT, East Amherst, NY (US); Nicholas Alexander POLOMOFF, Hopewell Junction, NY (US); Sathyanarayanan RAGHAVAN, Ballston Lake, NY (US); Kishan JAYANAND, Cohoes, NY (US); Aakrati JAIN, Albany, NY (US); Mary MCGAHAY, Troy, NY (US)

(21) Appl. No.: 18/753,425

(22) Filed: Jun. 25, 2024

(51) Int. Cl. H01L 23/532; H01L 23/522; H01L 23/544

(52) U.S. Cl. CPC H01L 23/53209; H01L 23/5228; H01L 23/544; H01L 2223/54433

(57) ABSTRACT

Embodiments presented in this disclosure generally relate to anti-counterfeiting for integrated circuits (ICs). More specifically, embodiments disclosed herein are directed to an authenticity validation structure integrated within an IC's packaging. One embodiment includes an IC and a metal alloy wire. The metal alloy wire comprises one or more resistive elements, and a total resistance of the one or more resistive elements provides a validation value for the package to ensure the package is authentic.

### BACKGROUND

The present disclosure relates to authenticity validation, and more specifically, embodiments disclosed herein are directed to a validation structure within an IC's packaging, through which the authenticity of the IC can be verified.

In light of the rising demand for electronic devices and the associated high manufacturing costs, counterfeit ICs and other electronic components have increased significantly. Such an increase presents substantial challenges for the semiconductor industry, as these counterfeit ICs and electronic components may disrupt global supply chains, and once used, risk the performance and reliability of electronic devices. Current anti-counterfeiting methods, such as using simple serial numbers or printing basic marks on IC packaging, are insufficient as they can be easily bypassed by skilled counterfeiters. Therefore, to protect the integrity of supply chains and maintain the performance of electronic devices in this rapidly evolving market, more effective anti-counterfeiting measures are required.

### SUMMARY

One embodiment presented in this disclosure provides a package including an IC and a metal alloy wire. The metal alloy wire includes one or more resistive elements, and a total resistance of the one or more resistive elements provides a validation value for the package to ensure the package is authentic.

One embodiment presented in this disclosure provides an anti-counterfeiting method for an electronic component. The method generally includes embedding a metal alloy wire within a package of the electronic component, where the metal alloy wire comprises one or more resistive elements, measuring a total resistance of the one or more resistive elements at a defined temperature during a manufacturing phase, and recording the first total resistance as a validation value for authentication.

One embodiment presented in this disclosure provides an apparatus for authenticity validation of an electronic component. The apparatus generally includes a metal alloy wire, where the metal alloy wire comprises a plurality of resistive elements along its length. Each of the plurality of first resistive elements has a different resistance value, and a total resistance of the plurality of resistive elements provides a validation value for the apparatus to ensure the apparatus is authentic.

### BRIEF DESCRIPTION OF THE DRAWINGS

FIG. 1A depicts an example authenticity validation structure where resistive elements within a metal alloy wire are uncovered, according to some embodiments of the present disclosure.

FIG. 1B depicts an example authenticity validation structure where resistive elements within a metal alloy wire are encapsulated within a protective layer, according to some embodiments of the present disclosure.

FIG. 2 depicts an example authenticity validation structure comprising multiple metal alloy wires, according to some embodiments of the present disclosure.

FIG. 3 depicts an IC integrated with authenticity validation structures, according to some embodiments of the present disclosure.

FIG. 4 depicts an example method for integrating validation structures into IC packaging and recording resistance values during chip manufacturing, according to some embodiments of the present disclosure.

FIG. 5 depicts an example method for authenticating ICs with recorded resistance values during chip validation, according to some embodiments of the present disclosure.

FIG. 6 is a flow diagram depicting an example method for IC authenticity validation, according to some embodiments of the present disclosure.

### DETAILED DESCRIPTION

One embodiment presented in this disclosure provides a package including an IC and a metal alloy wire. The metal alloy wire includes one or more resistive elements, and a total resistance of the one or more resistive elements provides a validation value for the package to ensure the package is authentic. One advantage provided by such an embodiment is the improved IC's security and enhanced accuracy of IC authentication against counterfeiting.

In another embodiment, the validation value may be stored in a chain of custody document that associates the validation value with a batch number of the IC. The association of validation values with specific batch numbers allows to track the distribution of the IC through the supply chain.

In another embodiment, the validation value may be measured at a defined temperature during manufacturing. By controlling the temperature, the resistance reading of the validation value may be maintained consistent and accurate throughout the validation and manufacturing processes.

In another embodiment, the package may further comprise a second metal alloy wire that is placed in parallel with the first metal alloy wire, where the second metal alloy wire comprises one or more second resistive elements, and a total resistance of the one or more first resistive elements and the one or more second resistive elements provides a second validation value for the package to ensure the package is authentic. One advantage provided by such an embodiment is that the total resistance, derived from two metal alloy wires, provides a more robust and fault-tolerant measurement compared with a single wire configuration, enhancing the reliability and accuracy of the validation process.

In another embodiment, the second validation value may be stored in a chain of custody document that associates the second validation value with a batch number of the IC. The association of validation values with specific batch numbers allows to track the distribution of the IC through the supply chain.

In another embodiment, the second validation value may be measured at a defined temperature during manufacturing. By controlling the temperature, the resistance reading of the validation value may be maintained consistent and accurate throughout the validation and manufacturing processes.

In another embodiment, the one or more first resistive elements within the first metal alloy wire may be encapsulated within a protective layer. The encapsulation shields the resistive elements from environmental stresses and mechanical damage, therefore enhancing the durability and reliability of the metal alloy wire.

In another embodiment, each of the one or more first resistive elements may have a different resistance value. One advantage provided by such an embodiment is the ability to fine-tune the resistance of the metal alloy wire, improving the accuracy of IC authentication against counterfeiting.

One embodiment presented in this disclosure provides an anti-counterfeiting method for an electronic component. The method generally includes embedding a metal alloy wire within a package of the electronic component, where the metal alloy wire comprises one or more resistive elements, measuring a total resistance of the one or more resistive elements during a manufacturing phase, and recording the first total resistance as a validation value for authentication. The disclosed embodiment provides a reliable measure to verify the authenticity of the electronic component.

In another embodiment, the validation value may be stored in a chain of custody document that associates the validation value with a batch number of the electronic component. The association of validation values with specific batch numbers allows to track the distribution of the IC through the supply chain.

In another embodiment, the method may further comprise measuring, during an authentication phase, a second total resistance of the one or more first resistive elements at a same temperature the first total resistance was measured during the manufacturing phase, and validating the electronic component to be authentic upon determining that a discrepancy between the validation value and the second total resistance is below a threshold. One advantage provided by such an embodiment is the consistent and reliable validation process, which is established by replicating the original conditions under which the component's validation value was measured, and by setting up a defined threshold to tolerate minor discrepancies.

In another embodiment, the method may further comprise embedding a second metal alloy wire within the package of the electronic component in parallel with the first metal alloy wire, where the second metal alloy wire comprises one or more second resistive elements, measuring a second total resistance of the one or more first resistive elements and the one or more second resistive elements during the manufacturing phase, and recording the second total resistance as a second validation value for authentication. One advantage provided by such an embodiment is that the total resistance, derived from two metal alloy wires, provides a more robust and fault-tolerant measurement compared with a single wire configuration, enhancing the reliability and accuracy of the validation process.

In another embodiment, the second validation value may be stored in a chain of custody document that associates the second validation value with a batch number of the electronic component. The association of validation values with specific batch numbers allows to track the distribution of the IC through the supply chain.

In another embodiment, the method may further comprise measuring a third total resistance of the one or more first resistive elements and the one or more second resistive elements at a same temperature the second total resistance was measured during an authentication phase, and validating the electronic component to be authentic upon determining that a discrepancy between the second validation value and the third total resistance is below a threshold. One advantage provided by such an embodiment is the consistent and reliable validation process, which is established by replicating the original conditions under which the component's validation value was measured, and by setting up a defined threshold to tolerate minor discrepancies.

In another embodiment, the one or more first resistive elements within the first metal alloy wire may be encapsulated within a protective layer. The encapsulation shields the resistive elements from environmental stresses and mechanical damage, therefore enhancing the durability and reliability of the metal alloy wire.

One embodiment presented in this disclosure provides an apparatus for authenticity validation of an electronic component. The apparatus generally includes a metal alloy wire, where the metal alloy wire comprises a plurality of resistive elements along its length. Each of the plurality of first resistive elements has a different resistance value, and a total resistance of the plurality of resistive elements provides a validation value for the apparatus to ensure the apparatus is authentic. One advantage provided by such an embodiment is the improved security and enhanced accuracy for validating the authenticity of the electronic component against counterfeiting.

In another embodiment, the validation value may be stored in a chain of custody document that associates the validation value with a batch number of the electronic component. The association of validation values with specific batch numbers allows to track the distribution of the IC through the supply chain.

In another embodiment, the apparatus for authenticity validation of an electronic component may further comprise a second metal alloy wire that placed in parallel with the first metal alloy wire, where the second metal alloy wire comprises a plurality of second resistive elements disposed along its length, each of the plurality of second resistive elements has a different resistance value, and a total resistance of the plurality of first resistive elements and the plurality of second resistive elements provides a second validation value for the apparatus to ensure the apparatus is authentic. One advantage provided by such an embodiment is that the total resistance, derived from two metal alloy wires, provides a more robust and fault-tolerant measurement compared with a single wire configuration, enhancing the reliability and accuracy of the validation process.

In another embodiment, the plurality of first resistive elements within the first metal alloy wire may be encapsulated within a protective layer. The encapsulation shields the resistive elements from environmental stresses and mechanical damage, therefore enhancing the durability and reliability of the metal alloy wire.

In another embodiment, the first metal alloy wire may be embedded within a package of the electronic component. The encapsulation of metal alloy wire within the electronic component's package enables efficient authenticity validation without compromising the internal structure or functionality of the component.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In recent years, the semiconductor industry has witnessed a significant increase in the number of counterfeit ICs and other electronic components that enter the market. These counterfeit components often share the same appearance as authentic ones but fall short in performance and reliability. Once used, these counterfeit components may increase the likelihood of malfunction, potentially resulting in system failure in electronic devices. Conventional methods for verifying the authenticity of ICs and other electronic components often rely on visual inspection, which may involve checking the packaging for customer-specific serial numbers or distinctive marks. However, these methods can be easily bypassed by experienced counterfeiters using techniques such as replicating packaging designs or reusing old chips. Such practice makes it difficult to distinguish authentic parts from counterfeits solely based on external appearances.

The present disclosure addresses these challenges by providing techniques and apparatuses that can effectively verify the authenticity of electronic components. Unlike conventional methods that depend on easily replicable external features, the present disclosure integrates validation structures directly into the IC package. In some embodiments, the validation structure may include one or more metal alloy wires with embedded resistive elements. The authenticity of an IC may be confirmed by measuring the total resistance of these elements at a defined temperature (or as a function of temperature changes) and comparing it with pre-recorded values stored in a Chain of Custody (COC) document. In some embodiments, these pre-recorded values may be associated with specific batches of ICs, to ensure each batch can be accurately verified against its recorded resistance profile. The disclosed validation structure provides a higher level of security that is difficult for counterfeiting, as it requires precise knowledge of the resistive properties and batch-specific resistance values documented under controlled conditions.

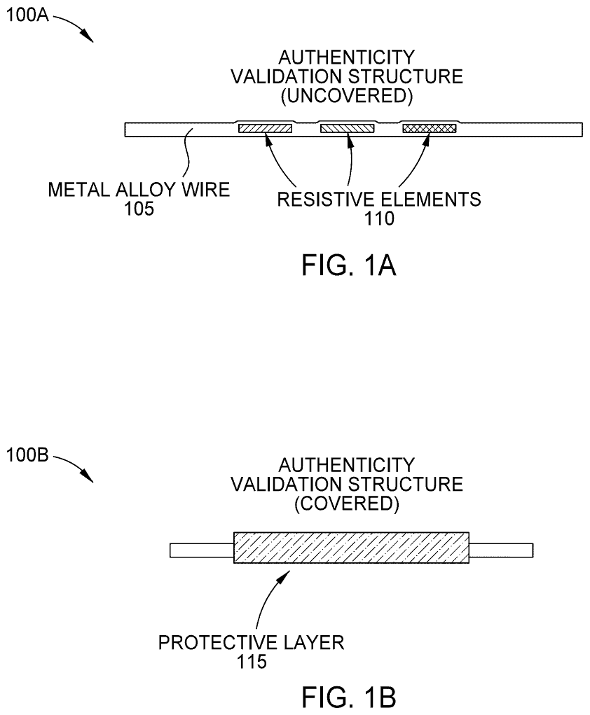

FIG. 1A depicts an example authenticity validation structure 100A where resistive elements within a metal alloy wire are uncovered, according to some embodiments of the present disclosure.

As illustrated, the example authenticity validation structure 100A includes a metal alloy wire 105. Within the wire 105, three resistive elements 110 are embedded at various locations along the length of the wire 105. Each resistive element 110 is configured to contribute to the total resistance of the wire 105. In some embodiments, the materials used for these resistive elements 110 may vary depending on the specific requirements of the chip manufacturer for electrical resistance, temperature coefficient, and durability. Common materials used for resistive elements 110 may include, but are not limited to, Nickel-Chromium (NiCr) alloys, platinum alloys, and Copper-Nickel alloys.

In some embodiments, the total resistance value of the validation structure 100A may be measured by connecting the ends of the metal alloy wire 105 to a resistance meter. The example authenticity validation structure 100A that depicts three resistive elements 110 embedded within the metal alloy wire 105 is provided for conceptual clarity. In some embodiments, the material, number, and positioning of resistive elements 110 within the metal alloy wire 105 may be determined by chip manufacturers, to precisely control the total resistance values of the validation structure 100A under predefined conditions (such as at a defined temperature or as a function of temperature changes). The resistance value may then be recorded in a Chain of Custody (COC) document associated with the manufacturer or a specific batch of ICs. When an IC with the example validation structure 100A is shipped to device manufacturers, they can verify the authenticity of the IC by measuring the total resistance of the validation structure 100A under the predefined conditions and comparing the results with those recorded in the COC document.

FIG. 1B depicts an example authenticity validation structure 100B where resistive elements within a metal alloy wire are encapsulated within a protective layer, according to some embodiments of the present disclosure.

Similar to the example authenticity validation structure 100A depicted in FIG. 1A, the validation structure 100B includes a metal alloy wire with three resistive elements at different locations along the wire. Each resistive element is configured to contribute to the overall resistance value of the wire. In contrast to FIG. 1A, FIG. 1B introduces an additional feature where the resistive elements are encapsulated within a protective layer 115. In some embodiments, the protective layer 115 may shield the resistive elements from surrounding components of the IC's package, to prevent potential interference and maintain accurate resistance measurement. In some embodiments, the protective layer 115 may consist of a variety of materials, including, but not limited to, silicon dioxide, polyimide, or silicon nitride. In some embodiments, the encapsulation of the resistive elements within the protective layer 115 may significantly improve the durability and reliability of the validation structure 100B.

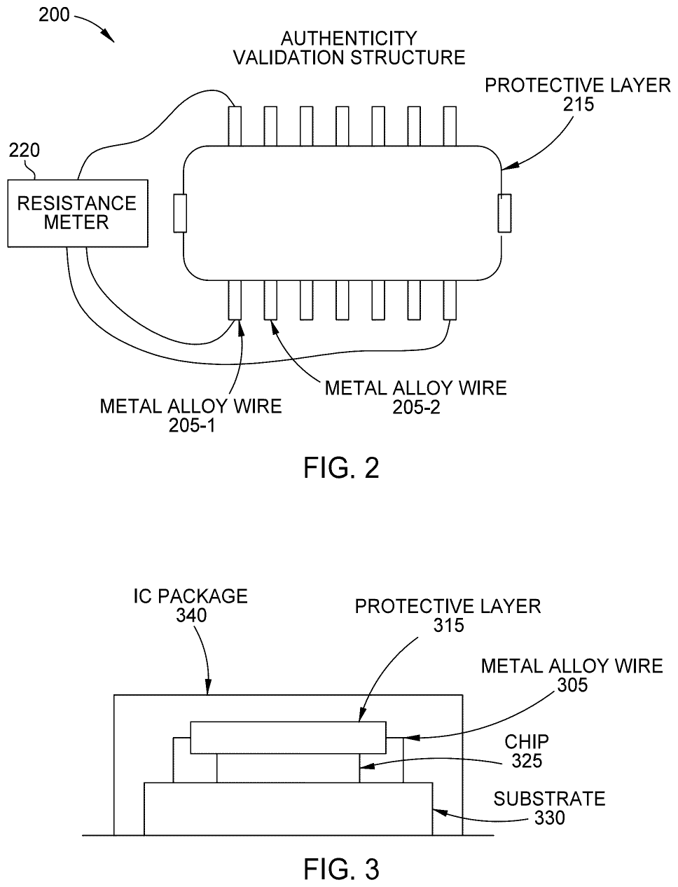

FIG. 2 depicts an example authenticity validation structure 200 comprising multiple metal alloy wires, according to some embodiments of the present disclosure.

As illustrated, the example authenticity validation structure 200 includes multiple metal alloy wires (like 205-1 and 205-2) arranged in parallel to each other. Each wire 205 in the array includes one or more resistive elements embedded along its lengths. These resistive elements are encapsulated within a protective layer 215 and collectively, the encapsulated wires are aligned to form a protective plane within the IC's package.

In some embodiments, the resistance of each metal alloy wire 205 may be measured individually by connecting the ends of each wire to a resistance meter 220. To ensure accuracy and consistency, the measurement may be performed under conditions defined in the COC document, such as at a defined temperature, or as a function of temperature changes.

In embodiments where wires 205 are not connected to each other, the total resistance of the entire authenticity validation structure 200 may be determined by measuring the resistance of each wire 205 separately and then summing up these values together. In embodiments where the wires 205 are connected in series, the total resistance of the authenticity validation structure 200 may be measured by connecting the ends of the series configuration to a resistance meter 220. In this configuration, the total resistance measured is equal to the sum of the individual resistance of each wire 205, as the current flows through each wire sequentially: Rₜₒₜₐₗ=R₁+R₂+R₃+ . . . +Rₙ. In embodiments where the wires are connected in parallel, the total resistance of the authenticity validation structure 200 may be measured by connecting the ends of the parallel configuration to a resistance meter 220, and the total resistance across parallel wires is calculated as follows: 1/Rₜₒₜₐₗ=1/R₁+1/R₂+1/R₃+ . . . +1/Rₙ. In some embodiments, the total resistance may then be compared to pre-recorded values specified in the COC document to verify the authenticity of the integrated chip.

In embodiments where resistance is measured as a function of temperature changes, it may involve assessing how the resistance of each metal alloy wire 205 (or the entire authenticity validation structure 200) varies across a range of temperatures. For example, the COC document may specify that the resistance should be tested from 20 degrees Celsius to 30 degrees Celsius. During the test, the resistance meter 220 may record the resistance at a defined interval within the temperature range and create a profile of how the resistance changes with temperature. The recorded resistance profile may then be compared to a pre-recorded profile specified in the COC document.

FIG. 3 depicts an IC 325 integrated with authenticity validation structures, according to some embodiments of the present disclosure.

As illustrated, various electronic components are enclosed within the IC's package 340. The chip 325 (also referred to in some embodiments as a semiconductor die or IC) consists of integrated electronic circuits and is the primary active component within the IC package 340. The chip 325 is mounted on a substrate 330. In some embodiments, the substrate 330 may provide mechanical support and electrical connections for the chip 325. Above the chip 325, the metal alloy wires 305 with protective layer 315 (which may correspond to 215 as depicted in FIG. 2) are aligned to maintain optimal functionality. The entire assembly, including the chip 325, substrate 330, metal alloy wires 305, protective layer 315, and any other components, is encapsulated within a package material to form the outer shell of the IC package 340.

In some embodiments, the package material may include epoxy, polymer, or any other materials that can protect the internal components from mechanical wear and environmental factors (e.g., moisture, dust, chemical exposure).

In some embodiments, such as when one or more metal alloy wires are utilized, the wires 305 with resistive elements may not be placed directly on top of the chip 325. Instead, each wire may be configured as a dummy outer lead that extends from the IC package 340 to a circuit board. Such design allows the wires to serve both structural and validation functions without interfering with the chip's operation.

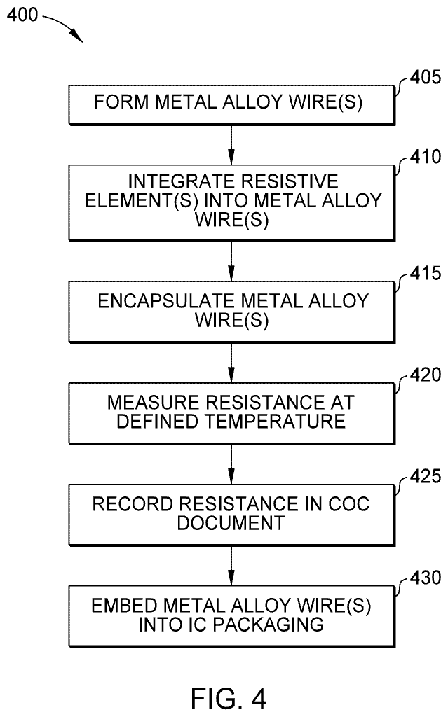

FIG. 4 depicts an example method 400 for integrating validation structures into IC packaging and recording resistance values during chip manufacturing, according to some embodiments of the present disclosure.

The method 400 begins at block 405, where a chip manufacturer selects metal alloy wires (e.g., 105 of FIG. 1, 205 of FIG. 2) used in an authenticity validation structure (e.g., 100A of FIG. 1A, 100B of FIG. 1B, or 200 of FIG. 2). In some embodiments, the chip manufacturer may customize the materials used in these alloy wires to make them unique to the manufacturer's brand or product line. Such customization may add another layer of protection by distinguishing the manufacturer's components from counterfeit ones. For example, device manufacturers (or any other entity in the supply chain) may verify the authenticity of an IC by analyzing the materials used in the alloy wires. In some embodiments, the detection of the elemental composition of the wire may be performed through spectroscopic analysis, X-ray fluorescence (XRF), or other material characterization techniques.

At block 410, the chip manufacturer integrates resistive elements (e.g., 110 of FIG. 1) into each metal alloy wire (e.g., 105 of FIG. 1). In some embodiments, the number of resistive elements, the materials used, and their positioning along the wire may be precisely determined by the chip manufacturer. These parameters may be set to achieve the desired total resistance, which is specific to the chip manufacturer or a particular batch. For authenticity validation structures that include multiple wires (e.g., 200 of FIG. 2), the overall number of wires incorporated may also be selected to make the cumulative resistance profile of the validation structure uniquely identifiable to the chip manufacturer or a specific batch. This configuration facilitates accurate control over the total resistance and, therefore improves the ability to authenticate and trace the origin of the IC.

At block 415, the resistive elements, once integrated, may be optionally encapsulated within a protective layer (e.g., 115 of FIG. 1). The encapsulation may protect the resistive elements from environmental factors and mechanical wear.

At block 420, the resistance of each encapsulated wire is measured under defined conditions, such as at a specified temperature or across a range of temperatures (like following a function of temperature) to observe how resistance varies with temperature changes. In embodiments where the authenticity validation structure includes multiple wires (e.g., 200 of FIG. 2), the total resistance may be determined by summing up the individual resistance values of each wire, or by using the formula for parallel resistances if the wires are connected in parallel.

Following the resistance measurement, at block 425, the results may be recorded in a COC document. As used herein, the COC documents refer to records that serve to track the integrity of components throughout their lifecycle. Within the COC document, in some embodiments, the resistance data measured at defined conditions may be linked to the specific chip manufacturer or a particular batch of chips produced by the manufacturer. In some embodiments, the COC document may serve as a benchmark for authenticity verification, where the recorded resistance data is referenced in future inspections to confirm that the ICs are indeed authentic and were produced by the specified chip manufacturer.

At block 430, one or more metal alloy wires with resistive elements are aligned and placed on top of an IC (e.g., 325 of FIG. 3) within the packaging framework. Following that, one or more package materials are applied to encapsulate the IC along with the embedded wires. In some embodiments, the applied materials for IC packaging may include epoxy or polymer. In some embodiments, the applied materials may form the outer shell of the IC package (e.g., 340 of FIG. 3) to provide structural support and protection for all internal components.

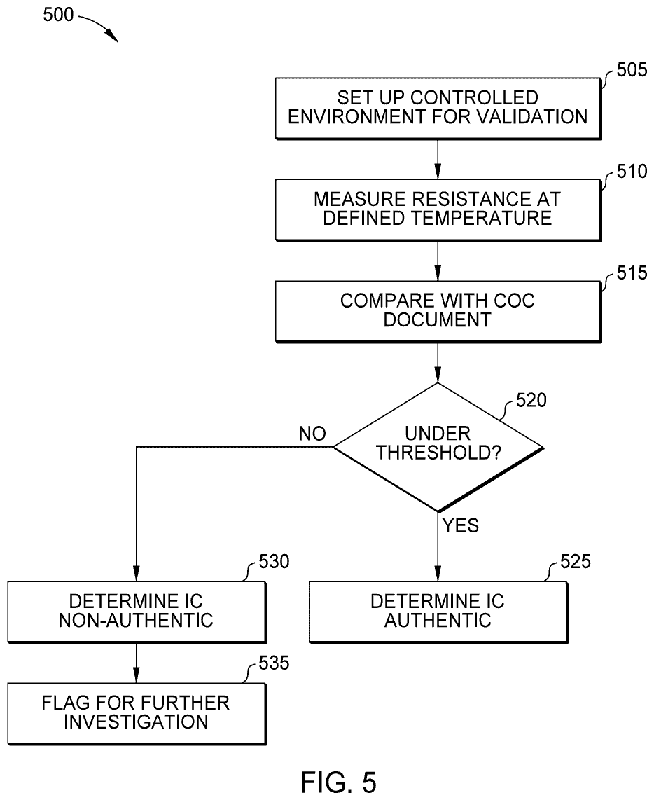

FIG. 5 depicts an example method 500 for authenticating ICs with recorded resistance values during chip validation, according to some embodiments of the present disclosure.

At block 505, a device manufacturer (or any other entity in the supply chain) receives an IC and sets up a controlled environment for validating the authenticity of the IC. In some embodiments, the temperature within the controlled environment may be adjusted to a predefined setting (e.g., 20 degrees Celsius) or follow a defined function of temperature changes (e.g., increasing from 20 degrees Celsius to 30 degrees Celsius), as specified in the COC document.

At block 510, the IC is placed within the controlled environment, and the resistance of the IC's validation structure is measured. In embodiments where the validation structure includes multiple wires (e.g., 200 of FIG. 2), the total resistance may be determined by summing the individual resistances of each wire, or by using the formula for parallel resistances if the wires are connected in parallel.

At block 515, the measured resistance values are then compared against those recorded in the COC document. In some embodiments, the comparison may involve statistical calculations to determine discrepancies between measured data and recorded data. In some embodiments, particularly when a more detailed analysis is required or when the data involves complex variations, the measured data may first be converted into graphs or other visual representations. These visual representations may highlight trends, outliers or inconsistencies more effectively than raw data, and therefore provide device manufacturers (or any other entity in the supply chain) a clearer picture of whether the IC meets the required specifications.

At block 520, the device manufacturer determines the authenticity of the IC based on the comparison results. If the measured resistance values are consistent with those recorded in the COC document or the discrepancy between these two data sets falls within a defined threshold, the method 500 proceeds to block 525, where the IC is confirmed as authentic. In some embodiments, if the recorded resistance value is associated with a specific chip manufacturer, the device manufacturer may then confirm the origin of the chip. If the discrepancy exceeds the threshold, the method 500 proceeds to block 530, where the IC is determined to be counterfeit. The IC is then, at block 535, flagged for further investigation. In some embodiments, alerts may be sent to relevant parties within the supply chain to initiate corrective actions or further scrutiny.

In some embodiments, minor discrepancies between the measured and recorded resistance values may be attributed to inherent variances in production, slight alternations in material properties over time, or environmental changes impacting the measurement. The threshold for discrepancies may be adjusted to accommodate these variables, allowing for minor, non-critical variations while maintaining a standard to protect against major variations that could indicate counterfeiting or component failure. In some embodiments, the threshold may be set at a percentage range of the recorded values, such as ±5%, based on historical data and/or industry standards for similar components.

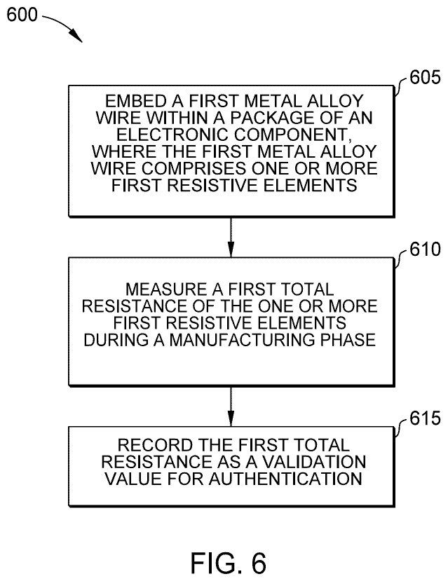

FIG. 6 is a flow diagram depicting an example method 600 for IC authenticity validation, according to some embodiments of the present disclosure.

At block 605, a first metal alloy wire (e.g., 205 of FIG. 2) is embedded within a package of an electronic component (e.g., 325 of FIG. 3), where the first metal alloy wire comprises one or more first resistive elements (e.g., 110 of FIG. 1).

At block 610, a first total resistance of the one or more first resistive elements (e.g., 110 of FIG. 1) is measured at a defined temperature during a manufacturing phase (as depicted by block 420 of FIG. 4).

At block 615, the first total resistance is recorded as a validation value for authentication (as depicted by block 425 of FIG. 4).

In some embodiments, the validation value may be stored in a chain of custody document that associates the validation value with a batch number of the electronic component.

In some embodiments, a second total resistance of the one or more first resistive elements may be measured at the temperature during an authentication phase, and the electronic component may be validated to be authentic upon determining that a discrepancy between the validation value and the second total resistance is below a threshold.

In some embodiments a second metal alloy wire may be embedded within the package of the electronic component in parallel with the first metal alloy wire, where the second metal alloy wire comprises one or more second resistive elements. A second total resistance of the one or more first resistive elements and the one or more second resistive elements may be measured at the defined temperature during the manufacturing phase. The second total resistance may be recorded as a second validation value for authentication.

In some embodiments, the second validation value may be stored in a chain of custody document that associates the second validation value with a batch number of the electronic component.

In some embodiments, a third total resistance of the one or more first resistive elements and the one or more second resistive elements may be measured at the temperature during an authentication phase. The electronic component may be determined to be authentic upon determining that a discrepancy between the second validation value and the third total resistance is below a threshold.

In some embodiments, the one or more first resistive elements within the first metal alloy wire may be encapsulated within a protective layer.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

While the foregoing is directed to embodiments of the present disclosure, other and further embodiments of the disclosure may be devised without departing from the basic scope thereof, and the scope thereof is determined by the claims that follow.

What is claimed is:

1. A package, comprising:
an integrated circuit (IC); and
a first metal alloy wire, wherein:
the first metal alloy wire comprises one or more first resistive elements, and
a total resistance of the one or more first resistive elements provides a validation value for the package to ensure the package is authentic.

2. The package of claim 1, wherein the validation value is stored in a chain of custody document that associates the validation value with a batch number of the IC.

3. The package of claim 1, wherein the validation value is measured at a defined temperature during manufacturing.

4. The package of claim 1, further comprising:
a second metal alloy wire that is placed in parallel with the first metal alloy wire, wherein:
the second metal alloy wire comprises one or more second resistive elements, and
a total resistance of the one or more first resistive elements and the one or more second resistive elements provides a second validation value for the package to ensure the package is authentic.

5. The package of claim 4, wherein the second validation value is stored in a chain of custody document that associates the second validation value with a batch number of the IC.

6. The package of claim 4, wherein the second validation value is measured at a defined temperature during manufacturing.

7. The package of claim 1, wherein the one or more first resistive elements within the first metal alloy wire are encapsulated within a protective layer.

8. The package of claim 1, wherein each of the one or more first resistive elements has a different resistance value.

9. An anti-counterfeiting method for an electronic component, comprising:
embedding a first metal alloy wire within a package of the electronic component, wherein the first metal alloy wire comprises one or more first resistive elements;
measuring a first total resistance of the one or more first resistive elements during a manufacturing phase; and
recording the first total resistance as a validation value for authentication.

10. The method of claim 9, wherein the validation value is stored in a chain of custody document that associates the validation value with a batch number of the electronic component.

11. The method of claim 9, further comprising:
measuring, during an authentication phase, a second total resistance of the one or more first resistive elements at a same temperature the first total resistance was measured during the manufacturing phase; and
validating the electronic component to be authentic upon determining that a discrepancy between the validation value and the second total resistance is below a threshold.

12. The method of claim 9, further comprising:
embedding a second metal alloy wire within the package of the electronic component in parallel with the first metal alloy wire, wherein the second metal alloy wire comprises one or more second resistive elements;
measuring a second total resistance of the one or more first resistive elements and the one or more second resistive elements during the manufacturing phase; and
recording the second total resistance as a second validation value for authentication.

13. The method of claim 12, wherein the second validation value is stored in a chain of custody document that associates the second validation value with a batch number of the electronic component.

14. The method of claim 12, further comprising:
measuring a third total resistance of the one or more first resistive elements and the one or more second resistive elements at a same temperature the second total resistance was measured during an authentication phase; and
validating the electronic component to be authentic upon determining that a discrepancy between the second validation value and the third total resistance is below a threshold.

15. The method of claim 9, wherein the one or more first resistive elements within the first metal alloy wire are encapsulated within a protective layer.

16. An apparatus for authenticity validation of an electronic component, comprising:
a first metal alloy wire, wherein:
the first metal alloy wire comprises a plurality of first resistive elements disposed along its length, wherein each of the plurality of first resistive elements has a different resistance value, wherein a total resistance of the plurality of first resistive elements provides a validation value for the apparatus to ensure the apparatus is authentic.

17. The apparatus of claim 16, wherein the validation value is stored in a chain of custody document that associates the validation value with a batch number of the electronic component.

18. The apparatus of claim 16, further comprising:
a second metal alloy wire that placed in parallel with the first metal alloy wire, wherein:
the second metal alloy wire comprises a plurality of second resistive elements disposed along its length, wherein each of the plurality of second resistive elements has a different resistance value, wherein a total resistance of the plurality of first resistive elements and the plurality of second resistive elements provides a second validation value for the apparatus to ensure the apparatus is authentic.

19. The apparatus of claim 16, wherein the plurality of first resistive elements within the first metal alloy wire are encapsulated within a protective layer.

20. The apparatus of claim 16, wherein the first metal alloy wire is embedded within a package of the electronic component.
